(19) United States
(12) Patent Application Publication
(10) Pub. No.: US 2012/0112370 A1
(43) Pub. Date: May 10, 2012

(54) TEMPLATE, METHOD OF FORMING TEMPLATE, AND METHOD OF MANUFACTURING SEMICONDUCTOR DEVICE

(76) Inventor: Yoshihito KOBAYASHI, Hino-shi (JP)

(21) Appl. No.: 13/233,517

(22) Filed: Sep. 15, 2011

(30) Foreign Application Priority Data
Nov. 4, 2010 (JP) 2010-247701

(51) Int. Cl. H01L 23/544; H01L 21/027

(52) U.S. Cl. 257/797; 438/401; 257/E23.179; 257/E21.023

(57) ABSTRACT

According to one embodiment, a template includes a pattern part which is provided on a substrate and corresponds to a pattern of a semiconductor device, the pattern of the semiconductor device being to be transferred to a wafer, and an alignment mark part which is provided on the substrate, used for positioning of the substrate with respect to the wafer. The alignment mark part has a refractive index that is higher than a refractive index of the substrate.

### CROSS-REFERENCE TO RELATED APPLICATIONS

This application is based upon and claims the benefit of priority from prior Japanese Patent Application No. 2010-247701, filed Nov. 4, 2010, the entire contents of which are incorporated herein by reference.

### FIELD

Embodiments described herein relate generally to a template, a method of forming a template, and a method of manufacturing a semiconductor device.

### BACKGROUND

Miniaturization in interconnect and device patterns of semiconductor device are required since semiconductor device have been highly integrated. Therefore, a mask or a template, which has a minute pattern to be transferred onto a wafer, is formed.

Generally, electron beam lithography has been used for forming a mask or a template. However, electron beam lithography requires much time for forming a pattern, and requires high manufacturing cost.

Therefore, a technique of preparing a second template by using a first template by imprinting which can form a minute pattern has been studied.

In a manufacturing method of semiconductor devices, accuracy of positioning a template on which a pattern is formed on a substrate (such as a semiconductor wafer) on which the pattern is to be transferred is important for improvement in manufacturing yield. Therefore, a template through which light can be transmitted is provided with an alignment mark for position reference, and a mark which corresponds to the alignment mark of the template is also formed on a wafer. Positioning of the template and the wafer is performed by using these alignment marks.

### BRIEF DESCRIPTION OF THE DRAWINGS

FIG. 1 is a schematic cross-sectional view of a structure of a template according to a first embodiment.

FIG. 2A is a schematic plan view of the structure of the template according to the first embodiment.

FIG. 2B is a schematic plan view of the structure of the template according to the first embodiment.

FIG. 3 is a schematic diagram for explaining a method of manufacturing the template according to the first embodiment.

FIG. 4 is a schematic diagram for explaining the method of manufacturing the template according to the first embodiment.

FIG. 5 is a schematic diagram for explaining the method of manufacturing the template according to the first embodiment.

FIG. 6 is a schematic diagram for explaining the method of manufacturing the template according to the first embodiment.

FIG. 7 is a schematic diagram for explaining a method of manufacturing a semiconductor device.

FIG. 8 is a schematic diagram for explaining the method of manufacturing a semiconductor device.

FIG. 9 is a schematic cross-sectional view of a structure of a template according to a second embodiment.

FIG. 10 is a schematic cross-sectional view of a structure of a template according to a third embodiment.

### DETAILED DESCRIPTION

### Embodiments

Embodiments will be explained hereinafter with reference to drawings. In the following explanation, constituent elements which have the same function and structure are denoted by the same reference numeral, and overlapping explanation will be performed if necessary.

In general, according to one embodiment, a template includes a pattern part which is provided on a substrate and corresponds to a pattern of a semiconductor device, the pattern of the semiconductor device being to be transferred to a wafer; and an alignment mark part which is provided on the substrate, used for positioning of the substrate with respect to the wafer, and has a refractive index that is higher than a refractive index of the substrate.

### (1) First Embodiment

A template according to the first embodiment, a method of forming the template, and a method of manufacturing a semiconductor device using the template of the first embodiment will be explained hereinafter with reference to FIG. 1 to FIG. 8.

(a) Structure

A structure of the template of the present embodiment will be explained hereinafter with reference to FIG. 1.

A template 1 of the present embodiment is a template for forming a pattern of a semiconductor device.

The template 1 of the present embodiment has a pattern part 12 and an alignment mark part 11 on a substrate 10. For example, a quartz substrate (SiO₂ substrate) is used as the substrate 10.

The pattern part 12 has a minute depressed and projecting pattern. The pattern part 12 includes a plurality of projections which project from an upper surface of the substrate in a vertical direction with respect to the surface of the substrate. In a horizontal direction with respect to the surface of the substrate, a size of the projections in the width direction is, for example, 100 nm or less. In the present embodiment, the pattern part is also referred to as minute pattern, and the projections are also referred to as minute structure. The depressed and projecting pattern of the pattern part 12 has layout which corresponds to a circuit pattern such as an interconnect and a gate of a transistor that are formed on a semiconductor substrate (hereinafter referred to as a “wafer”), or a mask pattern for forming an interconnect or a gate of a transistor.

The alignment mark part 11 is provided at an end part of the substrate 10 (template 1) to be adjacent to the minute pattern part 12 at a predetermined interval. Another pattern may be provided between the minute pattern 12 and the alignment mark part 11.

The alignment mark part 11 is used as a reference pattern for positioning the template 1 with respect to the wafer (to-be-transferred substrate) when the minute pattern part 12 of the template 1 is transferred (imprinted) onto a surface of the wafer. A mark which corresponds to the alignment mark part 11 of the template 1 is formed on a predetermined position on the wafer.

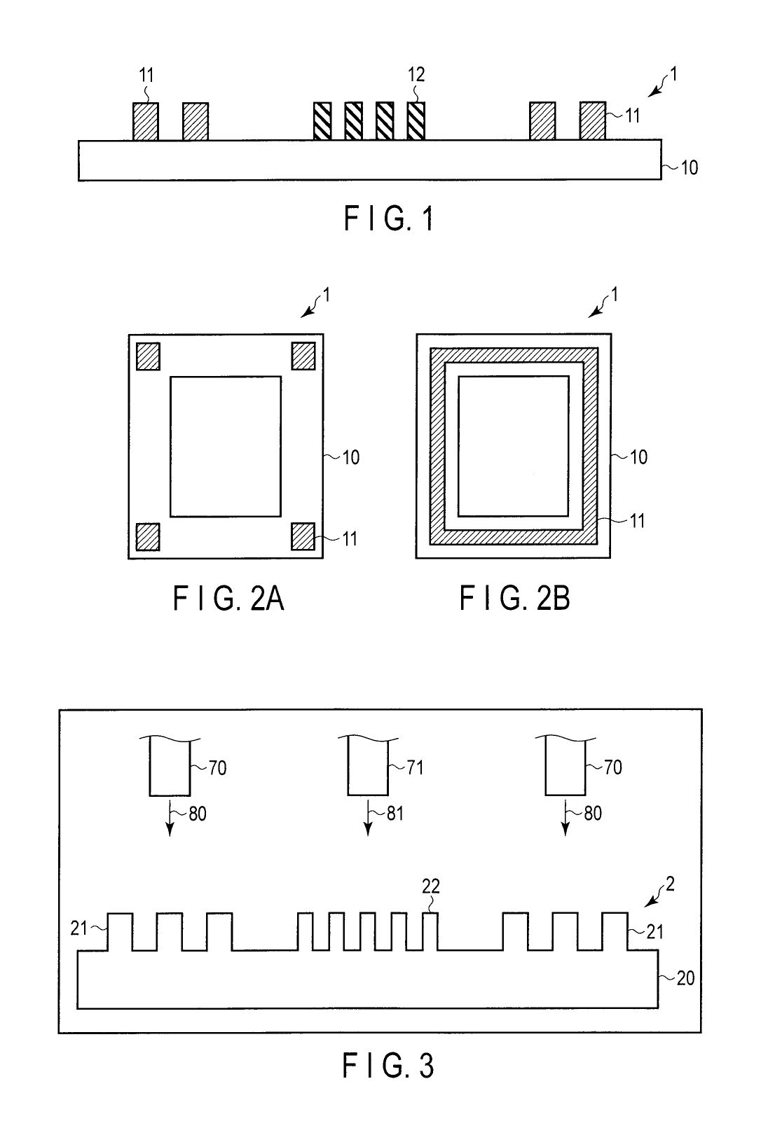

For example, as illustrated in FIG. 2A, the alignment mark part 11 is formed in each of four corners of the substrate 10. As another example, as illustrated in FIG. 2B, the alignment mark part 11 is provided on the substrate 10, and has a ring-shaped plane shape which surrounds the pattern part 12. The forming position and the shape of the alignment mark part 11 on the substrate 10 are not limited, as long as the template can be positioned with respect to the wafer.

In the present embodiment, the alignment mark part 11 is formed of material which is different from material of the substrate 10 of the template 1. The alignment mark part 11 has refractive index which is different from refractive index of the substrate 10 of the template 1. In addition, in the present embodiment, the alignment mark part 11 is formed of material which is different from material of the pattern part 12. The alignment mark part 11 has refractive index which is different from refractive index of the pattern part 12.

The alignment mark part 11 is formed of, for example, a silicon compound (such as SiO₂) which includes metal nanoparticles. For example, the alignment mark part 11 is formed of glass (also referred to as color glass) which includes metal oxide grains (also referred to as metal oxide nanoparticles). The alignment mark part 11 is formed by using a material solution (hereinafter referred to as a “high-refractive-index material solution”) which is formed of polysilane and silicone compound and metal oxide nanoparticles and a solvent. The solution for forming the alignment mark part 11 may include an additive such as a dispersing agent, a sensitizer, and a surface controller. In addition, pigment, ceramic powder, and metal powder may be used instead of the metal oxide nanoparticles. The metal oxide nanoparticles, pigment, ceramic powder, and metal powder are also referred to as impurity grains.

The minute pattern part 12 is formed of, for example, silicon-based compound (such as SiO₂), and does not include metal oxide nanoparticles. The minute structure of the minute pattern part is formed by using a material solution (hereinafter referred to as pattern material or glass forming solution) which is formed of polysilane and silicone compound and a solvent. For example, the solution for forming the minute pattern part 12 may include an additive such as a dispersing agent, a sensitizer, and a surface controller.

Since the material for forming the alignment mark part 11 includes metal oxide nanoparticles, pigment, ceramic powder, and metal powder, when these materials are used for forming the minute pattern, failure easily occurs in the formed pattern. Therefore, the minute pattern part 12 is desirably formed of a glass solution which does not include metal oxide nanoparticles or the like.

When the alignment mark part 11 is formed of silicon compound (glass) including metal nanoparticles, and the substrate 10 is formed of quartz, the refractive index of the alignment mark part 11 is higher than the refractive index of the substrate 10. When the alignment mark part 11 is formed of silicon compound (glass) including metal nanoparticles, and the minute pattern part 12 is formed of silicon oxide not including metal nanoparticles, the refractive index of the alignment mark part 11 is higher than the refractive index of the minute pattern part 12.

The refractive index of the alignment mark part 12 is, for example, about 1.6 to 1.8. The refractive index of the substrate (for example, quartz) 10 and the minute pattern part 12 is about 1.45, and the refractive index of the imprint agent (resin) is about 1.5.

The alignment mark part 11 is colored by, for example, adding metal oxide nanoparticles to silicon compound (material solution). The color of the alignment mark part 11 is changed, depending on the type of added impurities such as metal oxide nanoparticles.

The material for forming the alignment mark part 11 will be also referred to as high-refractive-index material hereinafter.

The details of the materials for forming the alignment mark part 11 and the minute pattern part 12 will be explained below.

The template 1 of the present embodiment has a structure in which the alignment mark part 11 is formed of material different from the material of the substrate 10 and the minute pattern 12. For example, the refractive index of the alignment mark part 11 is higher than the refractive indices of the substrate 10 and the minute pattern part 12.

Therefore, in the manufacturing process of a semiconductor device, when the template 1 supplied with imprint agent is positioned on the wafer, a boundary between the imprint agent and the alignment mark part 11 of the template 1 is clear since there is difference in refractive index between the imprint agent and the alignment mark part 11.

Therefore, it is possible to easily recognize the position of the alignment mark part 11 of the template 1, and accuracy of positioning of the template 1 on the wafer is improved.

In addition, the template 1 of the present embodiment has a structure in which only the alignment mark part 11 is formed of glass including impurities (such as metal oxide nanoparticles), and the substrate 10 and the minute pattern part 12 are formed of glass (such as SiO₂) including small impurities.

Therefore, according to the template 1 of the present embodiment, when the pattern of the template 1 is transferred (imprinted) onto the wafer, dispersion of impurities due to the template 1 into a pattern formation region of the wafer is reduced, in comparison with the case where the whole template is formed of glass including impurities. This results in improvement in manufacturing yield of the semiconductor devices.

As described above, according to the template of the present embodiment, it is possible to provide a template which can be easily positioned with respect to the wafer.

(b) Example of Material

The following is explanation of the material used for the template 1 of the present embodiment.

In the present embodiment, various glass solutions and resin solutions may be used as the material solution for forming constituent members of the template. Examples of components included in the glass solutions and the resin solutions are lead glass, bismuth glass, tin glass, phosphate glass, silica glass, glass which is formed of a siloxane component and an organic solvent such as alcohol that solves the component, alkylsiloxane polymer, alkylsilsesquioxane polymer, silsesquioxane hydride polymer, and alkylsilsesquioxane hydride polymer. The refractive index of the formed member may be controlled by further adding an additive (such as a vitreous former, an organic binder, pigment, ceramic powder, and metal powder) to these solutions.

The following is more specific explanation of the materials for forming the template.

The material (first material, high-refractive-index material) for forming the alignment mark part and the material solution (first material solution) are formed of polysilane, silicone compound, impurity particles (such as metal oxide nanoparticles), and a solvent. The material solution further includes an additive such as a dispersant, a sensitizer, and a surface controller.

Polysilane is a high molecule, a main chain of which is formed of only silicon atoms (Si). Polysilane may be a straight-chain type or a branched-chain type. Polysilane of a branched-chain type has good solvability and compatibility for a solvent and silicone compound, and excellent film formability. Therefore, in the present embodiment, it is desirable to use polysilane of a branched-chain type, rather than polysilane of a straight-chain type. A weight-average molecular weight of polysilane is 5000 to 50000, more preferably 10000 to 20000. Polysilane may include silane oligomer, if necessary. The content of silane oligomer is 5 to 25 wt %.

As the silicone compound, a silicone compound which is compatible with polysilane and an organic solvent is used. A weight-average molecular weight of the silicone compound is 100 to 10000, more preferably 100 to 5000. The silicone compound includes a silicone compound including double bonds, if necessary. The content of the silicone compound including double bonds for the total quantity of the silicone compound is 20 to 100 wt %, more preferably 50 to 100 wt %. A chemical group which forms a double bond in the silicone compound including double bonds is preferably a vinyl group, an aryl group, an acryloyl group, and a methacryloyl group. For example, a silicone compound which is generally called a silane coupling agent and has double bonds may be used as the silicone compound including double bonds.

The weight ratio of polysilane to the silicone compound is 80:20 to 10:90, more preferably 70:30 to 40:60. By including the silicone compound of such a weight ratio in the material solution, the material solution is sufficiently cured when the solution is cured, and a glass film (alignment mark part or pattern part) which includes very few cracks is formed.

Examples of the metal oxide nanoparticles added to the high-refractive-index material solution (alignment mark part) are lithium, copper, zinc, strontium, barium, aluminum, yttrium, indium, cerium, silicon, titan, zirconium, tin, niobium, antimony, tantalum, bismuth, chromium, tungsten, manganese, iron, nickel, ruthenium, alloy thereof, and an oxide of alloy thereof. The composition of oxygen in a metal oxide depends on a charge number of the metal. As a metal oxide, it is preferable to use zircon oxide, titanium oxide, and zinc oxide. By using them, it is possible to obtain a glass film which has a desired refractive index (high refractive index) and excellent transparency.

The average particle size of the metal oxide nanoparticles is 1 nm to 100 nm, more preferably 1 nm to 50 nm.

50 to 500 parts by weight, more preferably 100 to 300 parts by weight, of the metal oxide nanoparticles are preferably contained per 100 parts by weight of polysilane. By containing the metal oxide nanoparticles in the above range in polysilane, it is possible to form a glass film (alignment mark part) which has a desired refractive index and excellent transparency.

The metal oxide nanoparticles can be obtained by using a desired proper method. For example, the metal oxide nanoparticles can be formed by using a wet method or a baking method. A commercial product such as a anozirconium-dispersed solution may be used as the metal oxide nanoparticles. Pigment, ceramic powder, or metal powder may be used instead of the metal oxide nanoparticles.

An organic solvent is preferable as the solvent. Examples of the solvent are a hydrocarbon-base solvent with a carbon number of 5 to 12, a hydrocarbon-halide-base solvent, and an ether-base solvent. Specific examples of the hydrocarbon-base solvent are an aliphatic solvent such as pentane, hexane, heptane, cyclohexane, n-decane, n-dodecane, and an aromatic solvent such as benzene, toluene, xylene, and methoxybenzene. Examples of the hydrocarbon-halide-base solvent are carbon tetrachloride, chloroform, dichloromethane, and chlorobenzene. Examples of the ether-base solvent are diethylether, dibutylether, and tetrahydrofuran.

The solvent is preferably used in a range where a polysilane concentration in the material solution is 10 to 50 wt %.

A specific example of the sensitizer is an organic peroxide. Organic peroxides act to double bonds of silicone compound and have an effect of promoting addition polymerization between double bonds. Any proper compound can be used as the organic peroxide, as long as the compound can efficiently insert oxygen between Si—Si bonds of polysilane. For example, it is possible to use peroxyester-base peroxide, or an organic peroxide using a benzophenone frame.

The sensitizer is contained in the material solution (or solvent) at a ratio of 1 to 30 parts by weight, more preferably 2 to 10 parts by weight, per 100 parts by weight of the total of the polysilane and silicone compound. By using the sensitizer in this range, oxidation of polysilane is promoted even under a nonoxidation atmosphere.

A specific example of the dispersing agent is a high molecule which has a comb structure that includes a metal oxide nanoparticle-affinitive chemical group in a main chain or a plurality of side chains and includes a plurality of side chains that form a solvent-affinitive part. As another example, a high molecule which has a metal oxide nanoparticle-affinitive group in a main chain, or a straight-chain high molecule which has a metal oxide nanoparticle-affinitive group in a mono-terminal of a main chain is used as the dispersant.

The metal oxide nanoparticle-affinitive group is a functional group which has high adsorption for surfaces of metal oxide nanoparticles. Examples of the metal oxide nanoparticle-affinitive group are a tertiary amino group, a quaternary ammonium group, a heterocyclic group having a basic nitrogen atom, an hydroxyl group, a carboxyl group, a phenyl group, a lauryl group, a stearyl group, a dodecyl group, and an oleyl group. Since the dispersing agent has a metal oxide nanoparticle-affinitive group, the dispersing agent can exhibit sufficient performance as protective colloid for the metal oxide nanoparticles.

The dispersing agent is contained in polysilane in a ratio of 10 parts by weight to 100 parts by weight per 100 parts by weight of polysilane. By using the dispersing agent, the metal oxide nanoparticles can be uniformly dispersed into the material solution (solvent) and the whole alignment mark part formed of the material solution.

An example of the surface controller is a fluorine-base surfactant. The surface controller is contained in a ratio of 0.01 parts by weight to 1.0 parts by weight per 100 parts by weight of the total of polysilane and the silicone compound. Using the surface controller improves applicability on the template (substrate).

When the minute pattern part and the alignment mark part are formed of different materials (have different refractive indices), the material solution (second material solution) for forming the minute pattern part is formed of a solution containing polysilane, a silicone compound and a solvent. In this case, the material solution for forming the minute pattern part does not include metal oxide nanoparticles. The material solution further includes a dispersing agent, a sensitizer, and a surface controller, as additives.

The composition and the concentration of the material solution for forming the minute pattern part 12 are the same as those of the material solution for forming the alignment mark part 11, except that the minute pattern part 12 and the material solution thereof do not contain metal oxide nanoparticles. The solution which contains polysilane, a silicone compound, and a solvent and does not contain metal oxide nanoparticles is also referred to as pattern formation solution.

When the material solution for forming the alignment mark part 11 is not compatible with the material solution for forming the minute pattern part 12, that is, when the material solutions are not compatible with each other, when the alignment mark part 11 is adjacent to the minute pattern part, the materials thereof are mixed at the boundary between them, and a non-uniform film is formed. Therefore, the material solution for forming the minute pattern 12 is preferably compatible with the high-refractive-index solution for forming the alignment mark part 11. By using the material solutions which are compatible with each other, a uniform film can be formed on the substrate even when the materials of the alignment mark part and the minute pattern part are mixed in the case where the alignment mark part is adjacent to the minute pattern part.

The substrate 10 for forming the template 1 is, for example, a quartz substrate (a synthetic SiO₂ substrate, glass substrate). By using quartz for the substrate 10 of the template 1, an Si—O—Si bond is formed also between an Si atom of the substrate 10 and the material solution of the alignment mark part 11. Thereby, it is possible to realize very strong adhesion between the substrate 10 and the alignment mark part/pattern part 11 and 12. The material of the substrate is not specifically limited, but material other than quartz may be used. The substrate is preferably subjected to surface treatment to improve adhesion between the substrate and the alignment mark part/patter part. The method of surface treatment for improvement of adhesion is not specifically limited.

(c) Method of Forming Template

(c-1) First Forming Method

A method of forming the template of the present embodiment will be explained with reference to FIG. 3 to FIG. 5. FIG. 3 to FIG. 5 are cross-sectional views of manufacturing steps in the method of forming the template of the present embodiment.

The template 1 of the present embodiment is formed by an imprinting technique using two templates. In the technique, a pattern of a first template is imprinted on a substrate, and thereby a second template is formed.

As illustrated in FIG. 3, a first template 2 which includes an alignment mark part 21 and a minute pattern part 22 is formed.

The first template 2 serves as a form for forming the template of the present embodiment. The template 2 which serves as a form will be referred to as the master template 2 hereinafter. The master template 2 includes the alignment mark part 21 which corresponds to a shape of the alignment mark part of the template to be transferred (imprinted), and a minute pattern part 22 which corresponds to a shape of the minute pattern part of the template to be transferred. The alignment mark part 21 of the master template 2 will be referred to as master alignment mark part 21, and the minute pattern part 22 of the master template 2 will be referred to as master pattern part 22. The master alignment mark part 21 and the master pattern part 22 are formed on the substrate 20.

The pattern of the master template 2 is obtained by inverting the pattern of the template which is formed (transferred) by using the master template 2 by imprinting. The patterns 21 and 22 of the master template and the patterns of the template to be formed have negative-and-positive relationships.

The master template 2 is formed of, for example, quartz. However, the master template 2 may be any template that has a surface on which a minute depressed and projecting pattern is formed, and the material thereof is not limited.

The master template 2 is preferably subjected to surface treatment by using a mold releasing agent or the like, to improve mold releasability when members which are formed of the material solutions supplied to the master template 2 are released from the master template 2. The method of the surface treatment is not specifically limited.

As illustrated in FIG. 3, material solutions 80 and 81 are selectively supplied from supply ports 70 and 71 to respective predetermined pattern parts, that is, the master alignment mark part 21 and the master pattern part 22 of the master template 2, respectively, by using an inkjet method or the like. The material solutions 80 and 81 are material solutions for forming the alignment mark part and the minute pattern part, respectively, of the template which is formed by imprinting. When the inkjet method is used for supplying the material solutions, two material solutions 11A and 12A are substantially simultaneously supplied onto the master template 2.

The material solution (impurity particle solution or high-refractive-index material solution) 80 which includes metal oxide nanoparticles is supplied to the master alignment mark part 21. The material solution (pattern formation solution) 81 which does not include metal oxide nanoparticles is supplied to the master pattern part 22.

The method of supplying the material solutions to the template 2 is not limited to the inkjet method, but another method may be used to supply the material solutions 80 and 81 onto the master template 2.

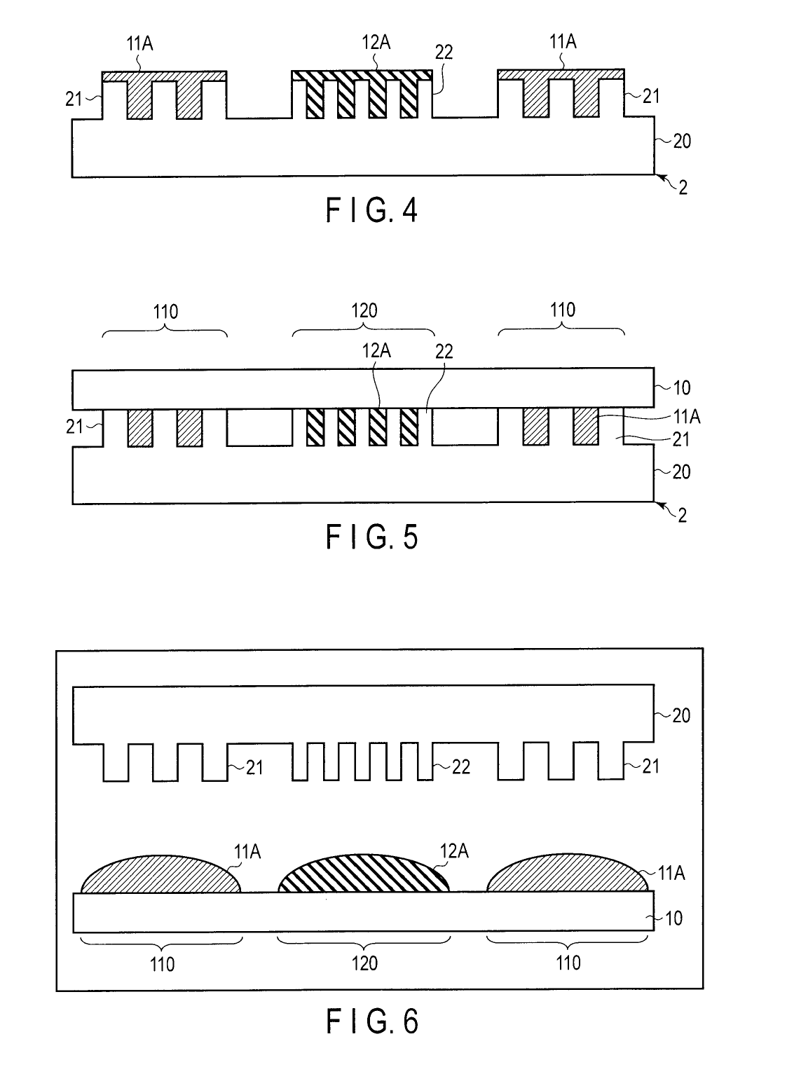

Thereby, as illustrated in FIG. 4, in the present embodiment, the high-refractive-index material solution 11A is selectively supplied to the master alignment part 21 of the master template 2, and material solution 12A which is different from the high-refractive-index material solution is supplied to the master pattern part 22.

After the material solutions are supplied onto the master template 2, a substrate for forming a second template is adhered onto the master template 2 supplied with material solutions 11A and 12A, as illustrated in FIG. 5. In the adhesion, the substrate 10 is caused to adhere to the master template 2, such that a region (hereinafter referred to as an “alignment mark forming region”) 110 of the substrate 10, in which the alignment mark part is to be formed, is opposed to the alignment mark part 21 of the master template 2, and a region (hereinafter referred to as a “minute pattern forming region”) 120 of the substrate 10, in which the minute pattern part is to be formed, is opposed to the master pattern part 22.

Material solutions 11A and 12A are cured by thermal imprinting or optical imprinting, in a state where the substrate 10 is adhered to the master template 2. When the template is formed from the master template by imprinting, optical imprinting or thermal imprinting is used for curing material solutions 11A and 12A. The optical imprinting is a method of curing the material solutions by applying light (such as ultraviolet rays) to them. The thermal imprinting is a method of curing the material solutions by heating. The curing method is not limited to optical or thermal imprinting, as long as the material solutions can be cured.

By application of heat or light, Si—Si bonds of polysilane included in material solutions 11A and 12A are changed to Si—O—Si bonds, and the two material solutions 11A and 12A are cured (vitrified) from liquid into glass. The cured material solutions (glasses) 11A and 12A are bonded to the substrate 10.

After the material solutions are cured, the master template is released from the substrate 10. The adhesive force between the master template 2 and the material solutions is smaller than the adhesive force between the substrate 10 and the material solutions, due to surface treatment performed for the master template 2 for improvement in mold releasability. Therefore, the cured glasses are easily released from the master template 2.

Thereby, as illustrated in FIG. 1, the pattern which is obtained by inverting the pattern of the master template 2 is imprinted on the substrate 10, and the alignment mark part 11 for positioning and the minute pattern part 12 are formed on the substrate 10. The template 1 of the present embodiment is formed by the above process.

After the template 1 is formed, it is checked whether the minute pattern part 12 of the template 1 includes any defects or not, by using, for example, an inspection apparatus which has a predetermined optical system.

As described above, the alignment mark part 11 is formed of the material which is different from those of the substrate 10 and the minute pattern part 12, and thus the alignment mark part 11 has a refractive index which is different from refractive indices of the substrate 10 and the minute pattern part 12.

The minute pattern part 12 is formed of a silicon compound (glass) which does not include metal oxide nanoparticles, and has a refractive index which is almost equal to, for example, the refractive index of the substrate 10.

On the other hand, the alignment mark part 11 is formed of a silicon compound (high-refractive-index glass) including metal oxide nanoparticles. The refractive index (about 1.6 to 1.8) of the alignment mark part is higher than the refractive indices (about 1.45 to 1.5) of the substrate 10 and the minute pattern part 12 of the template.

As described above, the alignment mark part 11 which has a different material and a different refractive index is formed on the same substrate as the substrate 10 on which the minute pattern part 12 is formed.

After the patterns 11 and 12 are cured, the substrate 10 and the template 1 may be subjected to heating. Oxidation of the polysilane is further promoted by heating, and the alignment mark/pattern 11 and 12 formed of the material solutions are further hardened. The heating may be performed before or after the template 1 is released.

By the forming process described above, the template 1 which has the alignment mark part 11 that has a refractive index higher than the refractive index of the substrate 10 or the minute pattern part 12 is formed by imprinting.

Therefore, when the template is positioned with respect to a wafer in an imprinting agent is supplied, the boundary between the imprinting agent and the alignment mark part 11 can be easily recognized, even when difference between the refractive index (about 1.5) of the imprinting agent and the refractive index (about 1.45) of the substrate 10 of the template 1 is small, since the refractive index of the imprinting agent is different from the refractive index of the alignment mark part 11 of the template 1.

Therefore, accuracy of positioning of the template 1 with respect to the wafer can be improved.

(c-2) Second Forming Method

A second method of forming the template of the present embodiment will be explained hereinafter with reference to FIG. 6. A difference between the second forming method and the first forming method will be explained hereinafter.

In the first forming method, after the material solutions are supplied to the alignment mark part and the minute pattern part of the master template 2, and the substrate of the template is adhered to the master template supplied with the material solutions, as illustrated in FIG. 3 and FIG. 4.

However, as illustrated in FIG. 6, the master template 2 may be adhered to the substrate 10 supplied with material solutions 11A and 11B.

The high-refractive-index material solution 11A is supplied to a region (referred to as an “alignment mark forming region”) 110 of the substrate 10, in which the alignment mark part is to be formed, by inkjet method or the like. Almost simultaneously with this, material solution 12A which is different from the high-refractive-index solution 11A is supplied to a region (referred to as a “minute pattern forming region”) 120 of the substrate 10, in which the minute pattern part is to be formed.

Then, after the master template 2 is adhered to the substrate 10 supplied with material solutions 11A and 12A, material solutions 11A and 12A are cured by optical imprinting or thermal imprinting. Thereafter, the master template 2 is released from the substrate 10. The alignment mark part 11 and the minute pattern part 12 remain on the substrate 10, and thereby the template 1 of the present embodiment is formed.

As described above, the high-refractive-index material solution 11A is supplied to the alignment mark forming region 110 of the substrate 10, and thereby the alignment mark part 12 which has a refractive index higher than the refractive index of the minute pattern part 12 or the substrate 10 can be formed on the substrate 10.

Therefore, according to the second forming method of the template of the present embodiment, it is also possible to provide a template which can be easily positioned with respect to a wafer, like the first forming method of the template of the present embodiment.

(d) Application Example

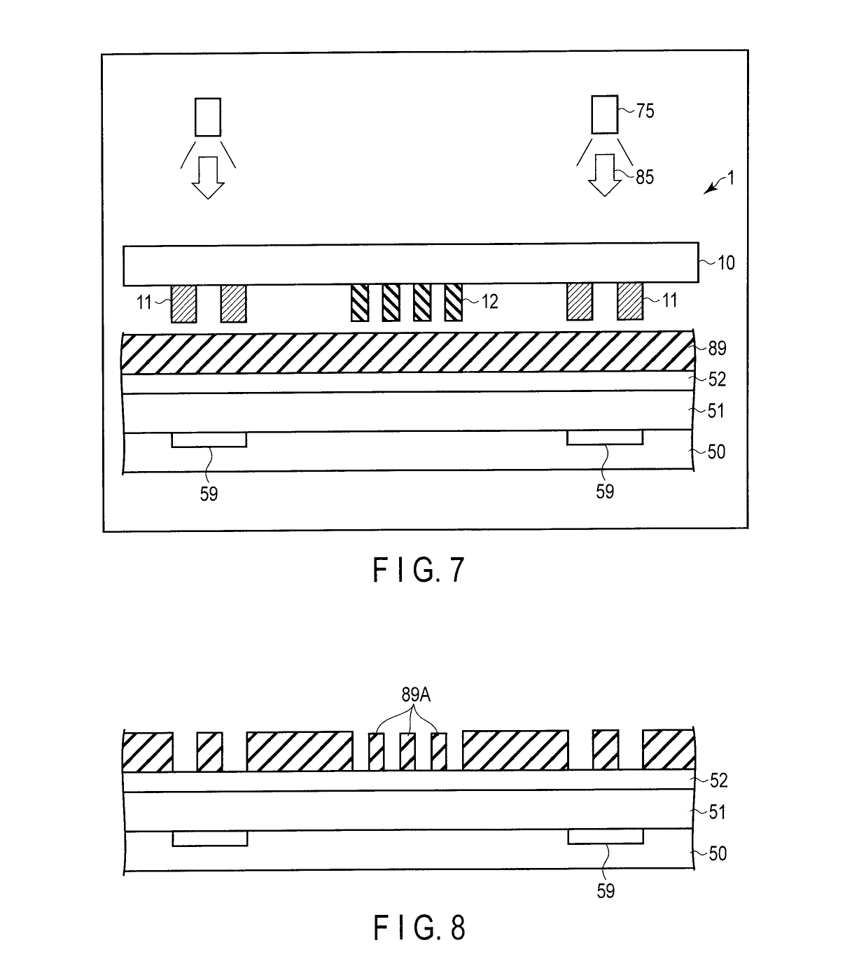

A method of manufacturing a semiconductor device using the template of the first embodiment will be explained hereinafter, as an application example of the template of the present embodiment, with reference to FIG. 7 and FIG. 8.

The template 1 of the present embodiment is used for, for example, transfer and formation of a pattern of a semiconductor device by imprinting.

A surface of a wafer 50 is provided with an alignment mark part (hereinafter referred to as a “wafer alignment mark part”) 59 which is adjacent to a device formation region of the wafer 50. The wafer alignment mark part 59 is provided to correspond to the alignment mark part 11 of the template 2.

For example, a layered structure 51 which includes an insulator and a conductor is deposited on the wafer 50 by, for example, chemical vapor deposition (CVD) or sputtering. For example, the conductor is a predetermined device or wire, and the insulator is an interlayer insulating film. A to-be-processed film 52 which is to be processed is deposited on an upper surface of the layered structure 51 by CVD or sputtering. The to-be-processed film 52 may be a conductive film (such as a metal film and a semiconductor film), or an insulating film. The to-be-processed film 52 may be directly deposited on the wafer 50. Although FIG. 7 shows an example in which the layered structure 51 and the to-be-processed film 52 covers a part above the wafer alignment mark part 59, the layered structure 51 and the to-be-processed film 52 may be removed from the part above the wafer alignment mark part 59, when the layered structure 51 and the to-be-processed film 52 have no light transmittance.

An imprinting agent 89 is supplied onto the to-be-processed film 52, and the imprint agent 89 is applied onto the wafer 50. A photo-curing resin or a thermal-curing resin is used as the imprinting agent 89. The resin of the imprinting agent has a refractive index of about 1.5.

Thereafter, the template 1 of the present embodiment is adhered to the wafer 50, to which the imprinting agent is applied. In the adhesion, positioning of the template 1 on the wafer 50 is performed by using the wafer alignment mark part 59 and the alignment mark part 11 of the template 1, such that the pattern of the minute pattern part 12 of the template 1 is imprinted on a predetermined position of the device forming region of the wafer 50.

Positioning of the template 1 with respect to the wafer 50 is performed by, for example, irradiating the alignment mark parts 11 and 59 with light 85 from a light source 75. For example, when the imprinting agent 89 is photo-curing resin, the light 85 from the light source 75 for positioning has a wavelength or a quantity of light which does not cure the imprinting agent 89, as a matter of course.

As described above, the alignment mark part 11 included in the template 1 of the present embodiment has a refractive index (for example, about 1.6 to 1.8) which is set higher than the refractive indices of the substrate and the imprinting agent, since, for example, metal oxide nanoparticles are added to the alignment mark part (or the material solution thereof).

Therefore, the boundary between the imprinting agent 89 and the alignment mark part 11 can be recognized, and it is possible to relatively easily align the alignment mark part 11 of the template 1 with the wafer alignment mark part 59, even in a state where the imprinting agent 89 is supplied onto the wafer 50.

After positioning of the template 1 with respect to the wafer 59 is ended, the imprinting agent 89 is cured by application of heat or light. When the imprinting agent 89 is a photo-curing resin, the substrate 10 and the minute pattern part 12 of the template 1 are formed of glass which includes few impurities (such as metal oxide nanoparticles). Therefore, the light 85 from the light source 75, which is transmitted through the substrate 10 and the minute pattern part 12, is applied to the imprinting agent 89, with hardly deteriorated transmittance. As a result, efficiency for curing the photo-curing resin is improved, such as reduction in the curing time.

In addition, according to the template 1 of the present embodiment, transfer accuracy and transfer efficiency of the minute pattern part 12 to the imprinting agent 89 are improved, and an imprint pattern with less distortion can be formed on the to-be-processed film 52. According to the template 1 of the present embodiment, the minute pattern part 12 does not include impurities, and thus it is possible to reduce dispersion of impurities caused by the template into the device forming region of the wafer 50.

As illustrated in FIG. 8, after the imprinting agent 89 is cured, the template 1 is released from the wafer 50. Thereby, an imprint pattern (transferred pattern) 89A of the template 1 is formed on the to-be-processed film 52.

Thereafter, the to-be-processed film 52 is processed by RIE or the like, with the formed imprint pattern 89A used as a mask.

As described above, the template of the present embodiment is applicable to a method of manufacturing semiconductor devices using imprinting.

As described above, according to the template 1 of the present embodiment, it is possible to perform positioning the template 1 of the present embodiment with respect to the wafer 50 with high accuracy. In addition, formation of a minute pattern by imprinting can be performed with high accuracy.

Therefore, manufacturing yield of semiconductor devices can be improved by manufacturing semiconductor devices with the template 1 of the present embodiment.

### (2) Second Embodiment

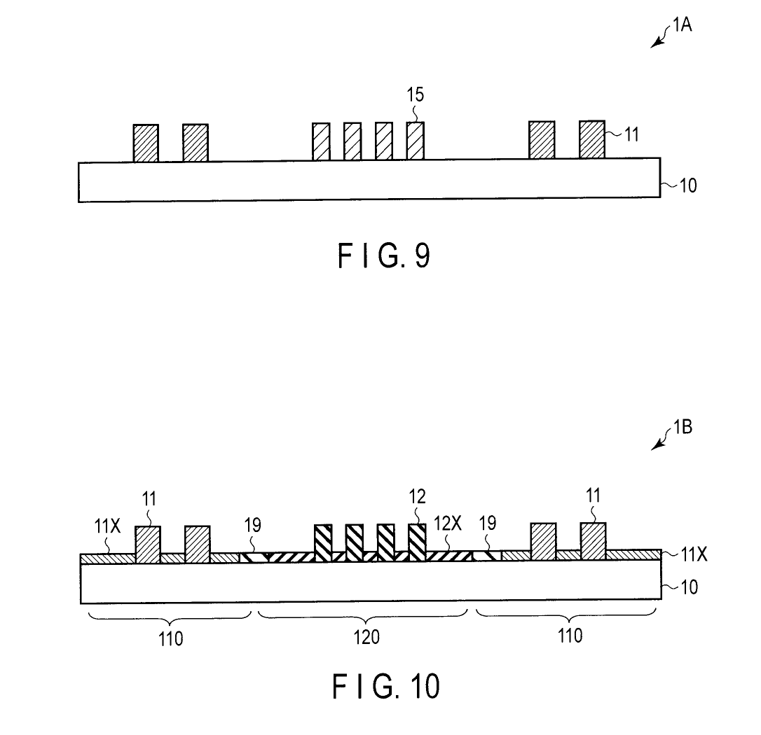

A template of a second embodiment will be explained hereinafter with reference to FIG. 9.

A difference between the present embodiment and the first embodiment will mainly be explained hereinafter, and explanation of matters which are common to the embodiments will be performed if necessary.

In a template 1A of the present embodiment, a minute pattern part 15 is formed of, for example, material which is different from material of a substrate 10. For example, the minute pattern part 15 is formed of a high-refractive-index material, and a refractive index of the minute pattern part 15 is set higher than a refractive index of the substrate 10.

As described above, since the refractive index of the minute pattern part 15 is different from the refractive index of the substrate 10, a position of the minute pattern 15 on the substrate 10 can relatively easily be recognized. Thereby, accuracy of detecting defects of the minute pattern part 15 can be improved.

There are cases where an optical system (such as the wavelength of the light source, light intensity, and the number of openings of the lens) used for positioning by the alignment mark is not the same as an optical system which performs inspection of defects of the template. Therefore, it is desirable that the materials suitable for the respective optical systems are used for the alignment mark part 11 and the minute pattern part 15, respectively.

A glass solution including metal oxide nanoparticles is used as the material solution for forming the minute pattern part 15, like the material solution for forming the alignment mark part 11. However, as described above, in consideration of diffusion of impurities into the device forming region of the wafer due to the template, it is desirable that the concentration of impurities (metal oxide nanoparticles) included in the material solution for forming the minute pattern part 15 and the minute pattern part 15 is lower than the concentration of impurities included in the material solution for forming the alignment mark part 11 and the alignment mark part 11.

The method of forming the template of the present embodiment is substantially the same as that of the first embodiment, except for the material which is supplied onto the master template 2 at the step of forming the template illustrated in FIG. 3.

Therefore, according to the template 1A of the second embodiment, a high-refractive-index material is used for the minute pattern part 15 together with the alignment mark part 11, and thereby the refractive index of the minute pattern part 15 is set higher than the refractive index of the substrate 10. Thereby, positioning of the template with respect to the wafer can be improved, and accuracy of inspection of defects of the template can be improved.

### (3) Third Embodiment

A template of a third embodiment will be explained hereinafter with reference to FIG. 10.

A difference between the present embodiment and the first and the second embodiments will mainly be explained hereinafter, and explanation of matters which are common to the embodiments will be performed if necessary.

As illustrated in FIG. 4 or FIG. 6, when the master template 2 is adhered to the substrate 10 in a state where material solutions 11A and 12A are supplied, there are cases where material solutions 11A and 12A are supplied to the surface of the substrate/template 1 in the vicinity of the alignment mark forming region 110 and the pattern forming region 120, or a boundary region between the alignment mark forming region 110 and the pattern forming region 120.

Thereby, a glass film 11X which is formed of the same material solution as that of the alignment mark part 11 is formed on the surface of the substrate 10 in the alignment mark forming region 110. In the same manner, a glass film 12X which is formed of the same material solution as that of the minute pattern part 12 is formed on the surface of the substrate 10 in the minute pattern forming region 120. Glass film 11X in the alignment mark forming region 110 has the same refractive index as that of the alignment mark part 11, and glass film 12X in the minute pattern forming region 120 has the same refractive index as that of the minute pattern 12.

In addition, material solution 11A for forming the alignment mark part 11 is compatible with material solution 12A for forming the minute pattern part 12, in the boundary region between the alignment mark forming region 110 and the minute pattern forming region 120.

In the case where the material solutions of two types are compatibly mixed in a boundary between the two forming regions 110 and 120, when the mixed material solution is cured, a glass film (compatible mix part) 19 which is obtained by compatibly mixing the two material solutions 11A and 12A is formed in the boundary region.

The concentration of the metal oxide nanoparticles (impurities) included in the compatible mix part 19 is lower than the concentration of the metal oxide nanoparticles included in the alignment mark part 11. In addition, the compatible mix part 19 has a refractive index which has a value between the refractive index of the alignment mark part 11 and the refractive index of the minute pattern part 12.

Although FIG. 10 shows the case where the compatible mix part 19 is formed in the template 1B, there are cases where the compatible mix part 19 and glass films 11X and 12X remain on the surface of a master template 2.

As described above, in the process of forming the template, material solutions 11A and 12A are supplied to the surface of the substrate 10 of the template, and glass films 11X and 12X and the compatible mix part 19 are formed on the surface of the substrate 10.

Also according to the template 1B of the third embodiment, positioning of the template with respect to the wafer can be improved, like the first and the second embodiments.

[Others]

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A template comprising:
a pattern part which is provided on a substrate and corresponds to a pattern of a semiconductor device, the pattern of the semiconductor device being to be transferred to a wafer; and
an alignment mark part which is provided on the substrate, used for positioning of the substrate with respect to the wafer, and has a refractive index that is higher than a refractive index of the substrate.

2. The template according to claim 1, wherein
the alignment mark part includes impurity particles.

3. The template according to claim 2, wherein
the impurity particles are at least one which is selected from a group including metal nanoparticles, metal oxide nanoparticles, pigment, ceramic powder, and metal powder.

4. The template according to claim 1, wherein
material of the pattern part is different from material of the alignment mark part.

5. The template according to claim 1, wherein
the pattern part does not include the impurity particles.

6. The template according to claim 2, wherein
the alignment mark part and the pattern part include the impurity particles, and concentration of the impurity particles in the pattern part is lower than concentration of the impurity particles in the alignment mark part.

7. The template according to claim 1, wherein
a compatible mix part which is obtained by compatibly mixing material of the pattern part with material of the alignment mark part is formed on the substrate between the pattern part and the alignment mark part.

8. The template according to claim 1, wherein
a refractive index of the pattern part has a value between the refractive index of the alignment mark part and the refractive index of the substrate.

9. The template according to claim 1, wherein
the refractive index of the alignment mark part is 1.6 to 1.8.

10. The template according to claim 9, wherein
a refractive index of the pattern part is 1.45 or more, and smaller than the refractive index of the alignment mark part.

11. The template according to claim 1, wherein
the alignment mark part is colored.

12. A method of forming a template, the method comprising:
supplying a first material which includes impurity particles to a first alignment mark part of a first template, and supplying a second material to a first pattern part of the first template, the first pattern part corresponding to a pattern of a semiconductor device, the pattern being to be transferred to a wafer;
adhering the substrate to the first template supplied with the first and the second materials; and
after curing the first and the second materials, releasing the substrate to which the cured first and second materials are joined, from the first template, and forming a second template which includes a second pattern part and a second alignment mark part that has a refractive index higher than a refractive index of the substrate.

13. The method according to claim 12, wherein
the first and the second templates are subjected to heating, after the first and the second materials are cured.

14. The method according to claim 12, further comprising:
inspecting the pattern part by using a first optical system,
wherein the first optical system is different from a second optical system which is used for positioning using the second alignment mark part.

15. The method according to claim 12, wherein
the second material includes the impurity particles, and concentration of the impurity particles in the second material is lower than concentration of the impurity particles in the first material.

16. The method according to claim 12, wherein
the impurity particles are at least one which is selected from a group including metal nanoparticles, metal oxide nanoparticles, pigment, ceramic powder, and metal powder.

17. The method according to claim 12, wherein
the first material is compatible with the second material.

18. A method of manufacturing a semiconductor device, the method comprising:
supplying a part between a template, which includes a pattern part that corresponds to a pattern of a semiconductor device and a first alignment mark part that has a first refractive index, and a wafer which includes a second alignment mark part, with an imprinting agent which has a second refractive index that is different from the first refractive index;
positioning the template with respect to the wafer by using the first alignment mark part and the second alignment mark part; and
transferring a pattern of the pattern part to the imprinting agent on the wafer.

19. The method according to claim 18, further comprising:
curing the imprinting agent;
and processing a layer on the wafer, by using the imprinting agent, to which the pattern of the pattern part is transferred, as a mask.

20. The method according to claim 18, wherein
the first alignment mark part includes impurity particles, and the pattern part does not include impurity particles.
